(19) United States
(12) Patent Application Publication
(10) Pub. No.: US 2010/0091459 A1
(43) Pub. Date: Apr. 15, 2010

(54) STREAMING-BASED MICRO/MINI CHANNEL ELECTRONIC COOLING TECHNIQUES

(75) Inventor: Zongqin Zhang, Wakefield, RI (US)

Correspondence Address: GAUTHIER & CONNORS, LLP, 225 FRANKLIN STREET, SUITE 2300, BOSTON, MA, 02110, US

(73) Assignee: BOARD OF GOVERNORS FOR HIGHER EDUCATION, STATE OF RHODE ISLAND AND PROVIDENCE, Providence, RI (US)

(21) Appl. No.: 12/345,699

(22) Filed: Dec. 30, 2008

Related U.S. Application Data
(63) Continuation of application No. PCT/US2007/074453, filed on Jul. 26, 2007.
(60) Provisional application No. 60/833,338, filed on Jul. 26, 2006.

(51) Int. Cl. H05K 7/20; F28D 15/02

(52) U.S. Cl. 361/701; 165/104.26; 29/592.1

(57) ABSTRACT

Micro-cooling technology for thermal control in the fabrication and operation of micro- and nano-scale such as high speed, high density micro scale electronic devices, micro sensors and micro machines Micro/mini heat exchangers and heat pipes have at least one channel through which the streaming flow is passed therethrough. The oscillating flow can be generated by diaphragms, vibrators, electrokinenatic force and thermal acoustic force.

### PRIORITY INFORMATION

This application is a continuation of International Patent Application No. PCT/US07/74453 filed on Jul. 26, 2007, which claims priority to U.S. Provisional Patent Application 60/833,338 filed on Jul. 26, 2006, all of which are incorporated herein in their entirety.

### BACKGROUND OF THE INVENTION

1. Field of the Invention

This invention relates generally to micro-cooling technology for thermal control in the fabrication and operation of micro- and nano-scale such as high speed, high density micro scale electronic devices, micro sensors and micro machines.

2. Description of the Prior Art

Micro-cooling technology has developed in response to the need for thermal control in the fabrication and operation of micro-and nano-scale such as high speed, high density micro scale electronic devices, micro sensors and micro machines Applications also exist in the miniaturization of such process plants as lab-on-chip (LOC) technology. In addition to meeting micro scale size requirements, microcooling devices must be capable of extremely high performance. For example, heat dissipation rates on the order of 100 W/cm² are required for the state-of-the-art computer chips while heat fluxes in excess of 14000 W/cm² are expected for Photon Source X-ray radiation. To meet these requirements, innovative cooling techniques through devices such as micro refrigerators, micro heat sinks, and micro heat exchangers are under development.

Numerous studies have been published in the last decade showed that thermal hydraulic performance of micro devices is somewhat different from convectional macro devices. In some cases, non-continuum effects may explain the deviations but not in others. Although most experimental studies showed that the critical Reynolds number (Re) from laminar to turbulent flow was lower than conventional values, some experimental results indicated that the conventional laminar friction factor correlation holds true for micro channel fluid flows but not for gaseous flows. However, most heat transfer studies reported that the Nusselt number for fluid flows was dependent on the Re number even in fully developed laminar flows, which is contrary to conventional laminar flow characteristics (Nishio, 2004).

The sustained drive for faster and smaller micro electronic device has led to a considerable increase in power density. The ability to effectively pump and enhance heat transfer in micro/mini channels is of immense technological importance. The micro channel heat exchanger has great advantages for high heat flux applications due to their high surface-to-volume ratio. Unfortunately, the small dimension of the micro channel leads to a large pressure drop and low Reynolds flow is usually associated with the low heat transfer coefficients. Therefore, forced convection micro heat exchangers require advanced micro pumping and heat transfer enhancement technologies. Using oscillatory flow to enhance the convective heat transfer coefficient in micro/mini channels is one of many new concepts and methodologies that have been proposed.

Considerable amount of studies on heat transfer in oscillating/pulsating macro channel flows have been published in the last few decades although the results were very inconclusive. Both enhancement and reduction of heat transfer rates have been found in experiments. Results varied with oscillation parameters, boundary conditions, fluid type and geometries. The inconclusiveness of oscillating channel flow was shown in more recent studies. For example, Zhao and Cheng (1995) reported that the average heat transfer rate increase with the dimensionless oscillation amplitude while Kim et al (1993) reported that at high pulsation frequencies, heat transfer is not affected by the addition of oscillation. Sert and Beskok (2003) reported that for the parameter range investigated, steady unidirectional forced convection is more effective than the reciprocating flow forced convection while Li and Yang (2000) and Fu et al (2001) reported that the length-averaged Nu number for oscillating flow is higher than that of steady flow. In spite of these differing conclusions, a common finding is that the changes in heat transfer rate due to pulsation are more pronounced in the entrance and exit region of the channel (Kim et al., 1993; Zhao and Cheng, 1995, Li and Yang, 2000). It is noted that most of the previous studies in micro systems have been concentrated on the steady flow characteristics, while the study of unsteady flow and heat transfer in micro channel has not been addressed (Park and Baek, 2004, Nishio, 2004). Sert and Beskok (2002) conducted a computer simulation of oscillatory heat transfer in micro heat spreader (MHS) and concluded that the aspect ratio of the micro channel has significant effects on the heat transfer performance. Most recently, Suzuki (2004) reported the oscillation flow heat transfer experiments in the mini channels with inner diameters ranging from of 0.3 mm to 0.8 mm. It concluded that the effective conductivity of their oscillation heat transfer device was about 25 times higher than that of copper and made this technique attractive for next-generation electronic cooling.

Flow streaming is a unique phenomenon in zero-mean-velocity oscillatory (reciprocating) flows. It is due to the flow profile discrepancies between the inflow and outflow during an oscillation cycle. Flow streaming is mostly inducted by flow in asymmetrical channel geometry.

A simple streaming-based microfluidic device to directly address these challenges. The device employs a mechanism of heat transfer enhancement using oscillatory. The device is a compact, reliable, cost-effective, easy to fabricate and easy to control mini/micro heat spreader.

There are some similarities between the micro channel acoustic streaming (AS) reported in the last few years and the pressure driven flow streaming (PS), since both flows are governed by the N-S equations. However, there are significant differences in:

mechanisms (Reynolds stress induced flow for AS modeled as compressible and body force driven) vs. asymmetrical boundary layer induced PS modeled as incompressible and pressure driven)

geometry (no specific geometry requirement for AS vs. specially designed geometry for PS)

operation parameters (frequency >100 kHz for AS vs. <0.1 kHz for PS and amplitude <0.1 mm for AS vs. >1 mm PS).

There have been a number of previous studies on flow streaming in ‘macro’ channel oscillating flows in the past few decades. However, the applications using streaming (except the High Frequency Ventilation (HFV) technique) have rarely been reported, including anything in ‘micro’ scales. Various geometry and flow arrangements were reviewed in the literature, including: streaming induced by a torsionally oscillated disk (Rosenblat, 1959 and 1960; Jones & Rosenblat, 1969), streaming adjacent to a cylinder oscillating along its diameter (Riley, 1965 and 1967), streaming appears in oscillating flow along a curved tube (Lyne, 1970), pressure-driven oscillatory flow within a tapered tube (Grotberg, 1984; Gayer & Grotberg, 1986), oscillatory flow through bifurcations (Haselton and Scherer 1982; Tarbell, Ultman and Durlofsky, 1982), and streaming in the channel entrance region (Goldberg, Zhang and Tran, 1999). However, the fundamental understanding as well as the practical application of the flow streaming during oscillatory flows is far from satisfactory. Flow streaming in micro-channels and heat transfer characteristics during streaming has received little attention.

### SUMMARY OF THE INVENTION

There are several potential advantages of micro/mini channel heat transfer using bi-directional streaming in zero-mean velocity oscillating flows:

For a typical mini/micro channel heat transfer applications, the aspect ratio (d/L, the ratio of channel diameter to length) of the geometry and flow Reynolds number are usually very low. Flows will be ‘fully developed’ within the length of a few diameters at the inlet for both steady and oscillating flows. Flow profiles are either parabolic (steady flow) or quasi-parabolic (oscillating flow) for most sections of the channel Fully developed flows are usually associated with the lowest temperature gradient at the wall in a ‘long’ straight tube, and consequently the lowest convective heat transfer coefficient. While flow streaming is induced by the discrepancies in velocity profile between the oscillating phases, at least one of the profiles is not ‘fully developed’. Therefore, in this regard, heat transfer is always enhanced with streaming flows compared with a typical ‘fully developed’ flow in micro/mini channel

Micro channel heat exchangers have great advantages for high heat flux applications due to their high surface-to-volume ratio. However, high surface-to-volume ratio leads to a large pressure drop. Design and fabrication of an advanced micro pump is always the major challenge in micro heat transfer applications. Fluid streaming is easy to create and can effectively transport fluid particles

Streaming flows preserve the advantages of oscillating flow in which: 1) boundary layers will periodically experience being developing-and-destroying at the two pipe entrances, and 2) it has a lower wall temperature lift.

Stream flows also preserve the advantage of unidirectional convection flow in which the flow can sweep a larger heat transfer surface area along the axial direction. For traditional oscillating flow heat transfer to be effective or to have a small temperature-lift, the fluid oscillating volume has to be greater than the channel volume so that all the heated fluid particles in the central heated region can be swept out. Therefore, a larger fluid oscillator is needed, which can be problematic for micro system design. This is particularly true for the heat transfer applications that the positions of the heat sinks have to be away from the heat sources. For oscillating streaming heat transfer, the oscillating volume can be only a fraction of the channel volume and still be capable of driving the heated fluids. Also, the positions of heat sinks can be designed away from the heat source.

Flow oscillation is inherently suitable for fluid mixing. It promotes active mixing (e.g., by recurring secondary flows at bifurcation or by inserting specially designed flow obstacles) as well as passive mixing for bi-directional flow streaming extends the fluid interface for diffusive mixing). Consequently, heat transfer coefficient will be enhanced.

The advantages of using steady bi-directional streaming in oscillating heat pipe channel flow include enhancing the rate of liquid return to the heating/evaporating section via the near-wall streaming velocity, and the rate of vapor flow via the core streaming velocity. Because of the aforementioned advantages, this heat pipe can operate in low gravity or anti-gravity conditions. The streaming-based heat pipe can provide the initial kick-out flow that is lacking for some heat pipe applications. The streaming-based heat pipe can overcome problems of dry-out conditions.

Almost all the previous oscillatory flow heat transfer studies focused on relatively simple geometries (e.g. straight tubes) with little flow streaming The combination of the two, micro/mini channel heat transfer characteristics during bi-directional streaming flow offers its unique features and many advantages for heat transfer enhancement.

All of the experimental observations and measurements reported in the literature were conducted in conventional channels, years before recent advances in the MEMS-technology. As the dimension of the flow passages is reduced, the ratio of surface-to-volume increase. Many parameters, which are negligible in macro-channel flow, become important. The very rich set of problems and behavior in bi-directional streaming during oscillating flows provides abundant opportunity for new applications including micro fluidic pumping.

These and other features and objectives of the present invention will now be described in greater detail with reference to the accompanying drawings, wherein:

### BRIEF DESCRIPTION OF THE DRAWINGS

FIGS. 1A and 1B are diagrams of flow streaming phenomena in a bifurcating structure and a taped channel;

FIG. 2 is an illustration to demonstrate the mechanisms of heat pipe performance enhancement using bi-directional streaming;

FIG. 3 are plots for steady and oscillating flow heat transfer;

FIG. 4 is a fabrication flow chart of a micro-channel;

FIG. 5 shows two piezoelectric bending diaphragms;

FIG. 6 shows a schematic drawing of a single test channel for heat transfer measurement;

FIG. 7 shows the distribution pattern of streaming velocity U and V as a function of radius position R and axial position Z in the entrance region of a circular tube;

FIGS. 8A-C show various set-ups of experiments on micro fluid mixing, propulsion and control; and

FIGS. 9 is a silicon wafer with three micro channel networks.

### DETAILED DESCRIPTION OF THE INVENTION

The concept of mini/micro channel heat exchanger using oscillating streaming flow has many potential advantages in practical applications, including that the proposed micro/mini heat transfer device is compact and reliable. This is because: a) most micro-fluidic systems require close-looped (or a two-way) piping system, e.g., pipes connected to the inlet and outlet of a pump, while the steady bi-directional streaming can be achieved in a one-way channel; b) no micro-valves are needed for streaming fluid propulsion. Various valves are needed in a typical micro pump system, such as check valves or pairs of diffusers/nozzles and micro-pump losses are dominated by the head losses in micro-valves; and c) this micro-fluidic system offers improved reliability because of its simple structure. There are no moving parts, other than the piezoelectric diaphragm action itself.

The application of streaming flow heat transfer is particularly attractive in micro systems. This is because: a) the volume of a micro system is so small that a large oscillation volume is easier to generate, b) the conventional forced convection heat transfer is difficult to accomplish commercially in micro/mini channels since the design and manufacture of a micro pump is a great challenge, and c) the research and development on other micro heat transfer device is still at its infant stage. All of these micro heat transfer techniques have their advantages and limitations. In a recent Navy report, Kuszewski and Zerby (2002) evaluated various miniature/micro heat spreading mechanisms including integrated thermoelectric devices, miniature/micro heat pipe, micro-machined synthetic jets and microfluidic devices and concluded that none of these technologies are able to achieve the high heat flux capacity within the required small form factor.

The distance a fluid can travel is limited by its oscillating volume for conventional oscillation flow heat transfer while there is no such problem for oscillation streaming flow heat transfer devices. Flow streaming can transport fluid particle to a distance far larger than the oscillation amplitude.

The proposed device can be easily manufactured using the current thin film deposition techniques. Piezoelectric diaphragm can be fabricated by simply depositing piezoceramic material to one or more diaphragms. Piezoelectric diaphragms have the inherent advantage of low voltage and high pump-head; it can also be designed to assemble multi-diaphragms in series to increase the total displacement. The advantages of compactness and the manufacture method described above would enable the device at a much smaller scale. It can be integrated into the microchip components at the design and fabrication stage, enabling a compact chip with an onboard cooling system to be employed, where conventional cooling strategies cannot be employed.

The use of piezoceramic material microfluidic system will be more scalable in device design and easy to control electronically. The surface temperature can be controlled with closed loop control strategies. For example, a thermocouple surface temperature measurement can provide the feedback signal. The rates of heat transfer are then controlled operating voltage and frequency. The power supply is one of the challenging problems for electrokinetic fluid propulsion device while the piezoelectric diaphragm can be designed to operate on regular powers supplies or even battery power, which provide engineers with greater design flexibility and make the micro system feasible.

Most micro heat transfer devices are unidirectional and the locations of heat source and sink are fixed. The proposed device is a heat spreader. There is no limitation on the location of the heat source. Therefore, it is more suitable for cooling of multi-task and variable-load microchips. Compared with the popular mini heat pipe device, the proposed device has no limitations of gravity direction, start-up and dry-out problem.

The heat transfer performance may be significantly improved if the two-phase flow (liquid-vapor) is utilized.

However, the proposed device also has some disadvantages. The major disadvantage of the device is its low efficiency in transport of fluids. This is because, compared with the main current of the oscillating channel flow, steady flow streaming is always a second order flow. Oscillatory flow increases friction losses. The possible solutions to remedy this are to increase the size of the micro-channel used, and to avoid using of high frequency flow oscillations.

The phenomena of flow streaming can occur in micro/mini channel oscillating flows The magnitude and the possible unique features that are different from its macro-scale counter part, as well as how to maximize the streaming effects, will be investigated. Flow streaming has a great potential for heat transfer enhancement, particularly in low Reynolds flows, since bi-directional flows increase temperature gradients and promote mixing in flow transversal direction. Flow streaming generated can be used to replace the traditional pumping method since bi-directional flow can effectively move fluids.

There are six independent variables that characterize the streaming process, e.g., the oscillating volume V_{T}, oscillation frequency f, fluid kinematics viscosity v, tube radius r, fluid particle displacement s̅( x̅) and one or more geometry variables (the variable could be the length of the tube L, the daughter tube radius r′, the bifurcation angle or the slope of the taper). It is assumed that the surface forces can be neglected. Variables can be combined using dimensional analysis to yield four dimensional groups; S=function (Reynolds number, Womersely number, non-dimensional geometry factor) where S is non-dimensional streaming displacement, defined as s= s̅( x̅)πr²/V_{T}, Reynolds number Re, (Re=ur/v, r is the channel radius, v is the fluid kinematics viscosity, and u=2V_{T}f/πr² with f, oscillation frequency) and Womersely number α(α=r(2πf/v)^{1/2}).

The mechanisms of flow streaming are different from those of acoustic streaming Acoustic flow streaming originates from attenuation of the acoustic field. The attenuation spatially reduces the vibrating amplitude of the acoustic wave and hence generates Reynolds stress distributions and drives the flow to form the acoustic streaming Acoustic streaming occurs in most geometries when an acoustic field exists, while the streaming flows that we studied are induced by the pressure-driven oscillating flows, and mostly occur in variable cross-sectional geometries. Also, the oscillating parameters are quite different. In most cases, the frequencies of acoustic vibration are much higher (>100 kHz vs. <0.1 kHz) while the amplitudes are much lower (<0.5 mm vs. >0.5 cm).

### Mechanisms of Flow Streaming and Heat Transfer Enhancement

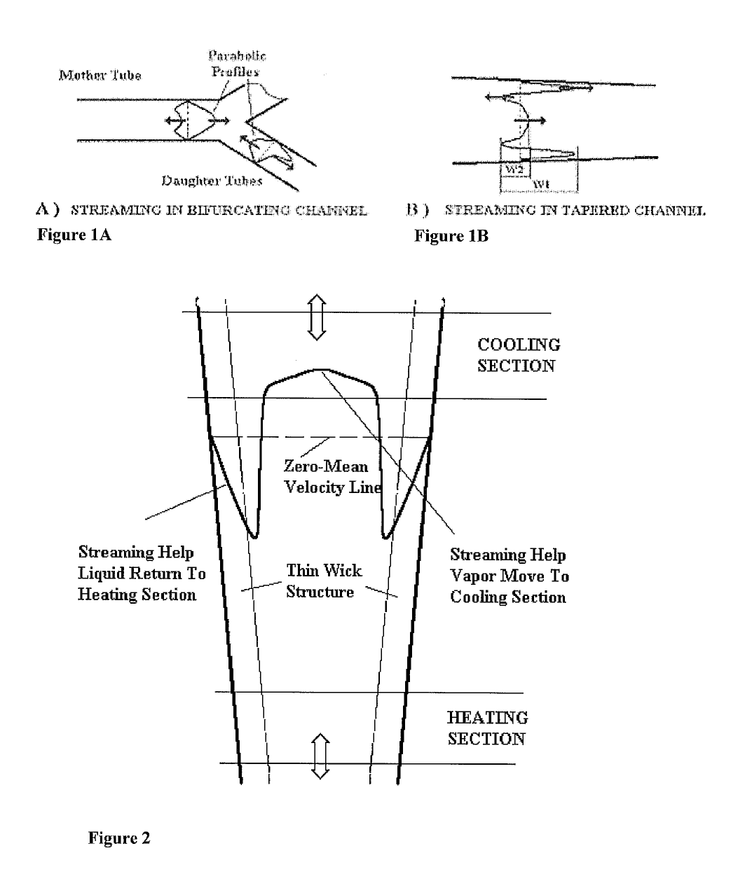

FIG. 1 illustrates two of the more common flow streaming phenomena in a bifurcating structure and a taped channel FIG. 1, Panel A, shows a qualitative picture of the steady axial velocity profiles of fluid in macro-channel bifurcation tube. During the inflow (to the right), parabolic velocity profile in the mother tube was split into half at the location of Uₘₐₓ when entering the daughter tubes, resulting in a nonsymmetrical profile with the maximum velocity skewed to the inner wall of daughter tube.

During the backflow (to the left), two fully developed flow profiles (with parabolic profiles) in the daughter tubes merges at the center of bifurcation and result in a ε [symbol] shaped symmetrical profile in the mother tube with a zero velocity at the center. Discrepancy in velocity profiles between inflow and backflow flow causes fluid particles near the walls drifted toward the mother tube (negative drift) while fluid particles near the centerline drifted to the daughter tubes (positive drift). This bi-directional streaming is very useful in promoting diffusive mixing; enhancing temperature gradient along the channel transverse direction and consequently improving heat transfer coefficient.

Also, a well-documented phenomenon is the spiraling secondary motion in bifurcation flows; two-celled flow in the daughter tube during inflows and four-celled in the mother tube during backflows. These secondary flows are induced by the centrifugal force as flows turning an angle from mother to daughter tube and vice versa. This secondary flow induced mixing is anticipated to be an additional mechanism for heat transfer enhancement. The magnitude of the secondary flow depends on Reynolds number, bifurcation angle, and transitional geometry connecting mother and daughter tubes. Its magnitude and the way to maximize it in micro-bifurcations will be investigated in the proposed program.

FIG. 1, specifically, Panel B, shows a qualitative picture of a streak deformation profile in a 2-D tapered macro-channel Both theoretical and experimental results showed bi-directional drift for all frequencies due to discrepancy between oscillating divergent (from narrow end to wide end) and convergent flows (from wide end to narrow end) in a tapered channel, which is dependent on the value of Womersley number and tapered angle. Similar to bifurcation networks, this bi-directional streaming will promote diffusive mixing; enhance temperature gradient in the direction of heat transfer and improve heat transfer coefficient.

FIG. 2, demonstrates the mechanisms of heat pipe performance enhancement using bi-directional streaming The key element of heat pipe principal is the bi-directional flow of liquid and vapor while the phenomenon of bi-directional streaming will further promote the bi-directional liquid and vapor flows in respective directions.

Comparison of Heat Transfer in Steady and Oscillating Channel flows

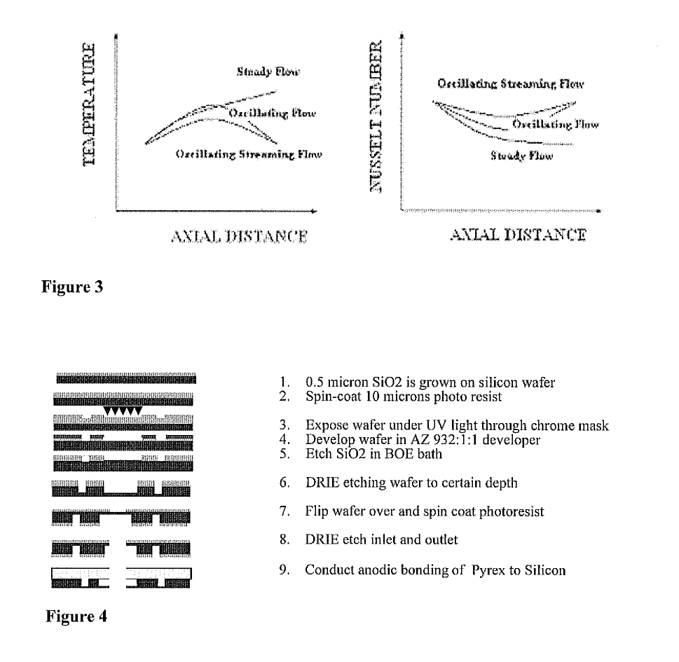

For a meaningful comparison of heat transfer performance between steady unidirectional flow and oscillating flows, the Reynolds number (based on the mean channel diameter and mean flow velocity) is kept the same. FIG. 3 illustrates the anticipated heat transfer behavior for oscillating streaming flow in the very same geometry with identical heating intensity. Plots for steady and oscillating flow heat transfer are adopted from the work by Fu et al. (2001) in a mini porous channel Panel A, sketches the average surface temperature distributions along the axial direction. For steady flow, the surface temperature increases along the flow direction and achieve a maximum value at the exit. While for oscillating flow, there are two thermal entrance regions. The surface temperature distribution curves are convex in shape. Fu et al. (2001) reported that the temperature-lift (the difference between the maximum and minimum wall surface temperature) for steady flow is between 1.5 to 3.5 times higher than that for oscillating flows. Since the local temperature of the substrate surface is more important than the average surface temperature and the reduction of the chip thermal stress caused by temperature-lift is very important in the application of electronic cooling and heat transfer by oscillating flow shows significant advantages due to lower temperature lift. It is anticipated that the streaming flow heat transfer will have lowest temperature lift. Panel B sketches the local Nu number along the axial direction. For steady flow, the Nu number is higher in the thermal entrance region. It approaches to a constant value for thermally developed flows. For oscillating flow, the local Nusselt number does not decrease monotonically. The local Nu number decreases first and then increases at the center point of the test channel Fu et al. (2001) demonstrated in their experiments that the length-averaged Nu for oscillating flow is higher than that of steady unidirectional flow for all Re numbers. The predicted Nu number for streaming flow will be highest among all three flows.

Based on the principle of energy conservation, the heat transferred from the wall must equal the increase in fluid enthalpy: Q=m′CΔT. Mass flow rates are the same for two types of flow with the same mean velocity and channel diameter while the ΔT, the mean fluid temperature changes from inlet to outlet, will be different. Oscillating flow heat transfer will produce a larger ΔT due to heat transfer in two thermal entrance regions. Oscillating streaming flow will have an even greater value of ΔT, caused by further mixing of high temperature streaming flows from the center of the heated pipe in addition to heat transfer in two thermal entrance regions.

One of the successful applications of flow streaming is the high-frequency-ventilation (HFV) technique in medical field. In contrast to conventional ventilation, which mimics normal breathing, HFV operates with tidal volumes much smaller than the anatomic dead space of the lungs at a higher rate of breath. The successive bifurcation networks coupled with the tapered lung airways geometry promote flow streaming and O₂/CO₂ exchange from mouth to deep lung alveolar region and vice versa. According to the conventional Weibel's lung model human lung may be modeled as continuously bifurcating branches started at the trachea as the 1^{st} airway generation. The pulmonary airways, where the O₂/CO₂ exchange takes place, are considered to start at 16^{th} generations. There are 131,072 airways at the generation 16^{th} and average airway radius r=237 micron. For a typical HFV respiratory data of tidal volume of 15.63 ml (measured at the trachea) and frequency of 16 Hz, the calculated Reynolds number Re and Womersely number α at the trachea are 3100 and 96, and at the generation 16^{th} are 2.1 and 2.3, respectively. Reynolds number and Womersely number decrease continuously as the airway generation number increase. Thus, the ranges of the Reynolds number, Womersely number and the channel dimensions proposed in our project has been tested in HFV applications, demonstrating the feasibility of fluid advection using streaming The feasibility of fluid pumping using streaming flow is further supported by the experimental observation of our preliminary work.

### Experimental Studies

### Fabrication of Micro Channels

### Fabrication Procedure

Micro-channels are be fabricated on a 100 mm diameter silicon wafer using standard photolithography and deep reactive ion (DRIE) etching techniques and then enclosed by bonding to a Pyrex 7740 wafer using anodic bonding method. The Pyrex glass will function as isolation and also facilitate visualization of the flow field in the microchannels. The procedure for fabrication is shown schematically in FIG. 4.

The process initiates with a double polished silicon wafer on which a 0.5 μm silicon dioxide layer is grown. A 5- [symbol] μm thick positive photoresist AZ 4620 (Clariant Co.) layer will be spin-coated on the wafer at a speed of 3500 rpm. After 30 minutes of pre-baking at 90° C., the wafer will be exposed to UV light for 12 seconds. During the exposure, the wafer was covered by a chrome photo-mask where the shape of micro-channels was depicted using Autocad. The wafer was developed in AZ440 developer (Clariant) to form a window in the photo-resist. Baking for an additional 30 minutes at 90° C. was needed before the wafer was wet-etched in 7:1 buffered oxide etcher (BOE) for 7 minutes to transfer the pattern to the silicon dioxide. The dry etching was performed on a Surface Technology System (STS) ICP etcher employing etching technology of the time multiplexed inductive couple plasma (TMICP) by employing a method developed by MIT (MIT 69A). After etching in STS, the wafer was put in Piranha etch (H₂SO₄: H₂O₂ 3:1) for 10 minutes to strip off the photo-resist on the surface of the silicon wafer. Then the wafers were placed in oxygen plasma asher for 30 minutes to further clean organics remaining on the surface after etching.

### Anodic Bonding

The micro-channels fabricated in silicon was enclosed with a glass plate using anodic bonding method, which has been well developed. The basic mechanism for anodic bonding can be found in many places. The inlet and outlet holes of the micro-channel were drilled on a Pyrex 7740 wafer by ultrasonic drilling. After drilling, both the silicon wafer and Pyrex was etched in Pirahna etch and cleaned in an oxygen plasma to remove the organics and to activate the bonding surface. The anodic bonding occurred below 300° C. to 400° C., which was provided by a normal hotplate. The inlets and outlets of the micro-channels was carefully aligned with holes on the Pyrex and the pair was placed on the hot plate. In the mean time, a power supply will be used to apply voltage of 2500 V across the silicon wafer and Pyrex wafer. The bonding took approximately 1.5 hr to complete.

### Experimental Apparatus

### Fluid Driving Mechanisms

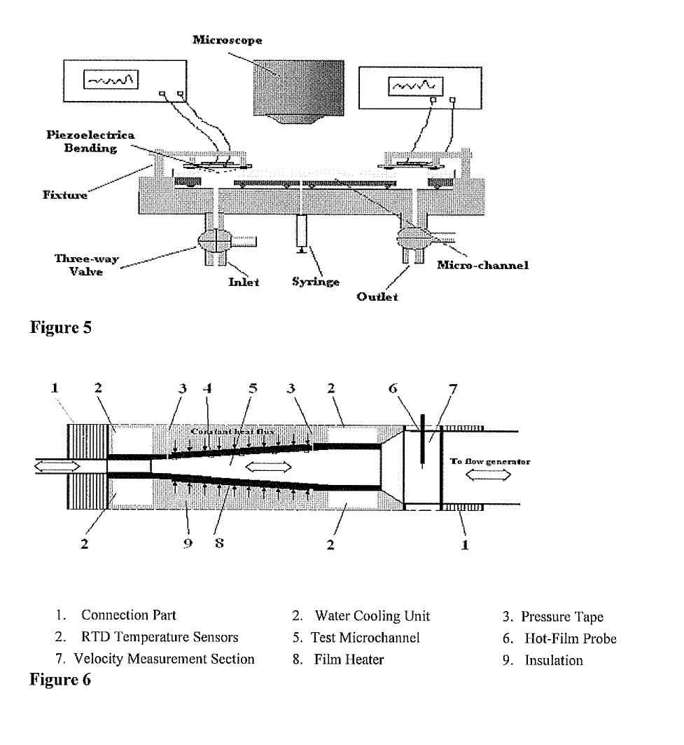

Two piezoelectric bending diaphragms as shown in FIG. 5, located at the inlet and outlet of the micro-channel systems, respectively, will generate the desired oscillating motion of the fluids. The piezoelectric diaphragms (bender plate) consist of a piezoelectric ceramic plate, with electrodes on both sides, attached to a metal plate with conductive adhesive. Applying a D.C. voltage across the electrodes of the piezoelectric diaphragm causes mechanical distortion due to piezoelectric effects. The distortion of piezoelectric ceramic plate expands (or shrinks) in the radial direction causing the metal plate to bend up (or down) depending on the polarity of the D.C. voltage. The repeated bending motion produced oscillating flows. The oscillating volume fraction and frequency, as well as profile, can be controlled by the electrical signal input. The piezoelectric diaphragm was able to generate a large force with a relative low voltage, although the displacement is small. However, because of the large surface area of the diaphragm to channel cross-section ratio, even a small displacement of the diaphragm generated a sufficient volume of liquid flow. For example, for a diaphragm diameter of 10,000 μm (the size of a dime) and a channel diameter of 100 μm (the size of human hair), a displacement ratio of 10,000 from diaphragm to fluids can be produced.

The commercial piezoelectric bending actuator-CBM (US Euro Tek, Inc.) was used in the experiments. The correlation of volume displacement vs. electrical signal input will be calibrated before experiments employing a bending actuator. Two piezoelectric diaphragms, located at each end of the test channel, will be used to provide accurate oscillating profiles. An elastic passive diaphragm will replace one of the actuators if initial experiment shows that harmonic motion of two piezoelectric diaphragms is difficult to achieve. For most experimental conditions, Model 100/15/010-M will be used. Its diameter is comparable to that of a nickel. The connection between piezoelectric actuators and the manifold is also designed to be exchangeable so that different piezoelectric actuators can be used to cover all ranges of experimental conditions, e.g., maximum volume displacement per stroke to 5 cubic mm, maximum frequency to 100 Hz and maximum force to 20 N. The calculated value of maximum force exerted on the diaphragm, for experimental conditions with Reynolds number (Re=20), flow oscillating frequency f=10 Hz, channel diameter d=100 micron, and channel length L=30 mm, is on the order of 10E-2 (N) when 100% water is used. The total volume of this micro channel is 0.3 cubic mm

### Experimental Setup

The silicon wafer and Pyrex wafer assembly have embedded micro-channel networks and firmly secured on the experimental platform by a wafer retainer as shown in FIG. 5. The platform was made of aluminum and the piezoelectric actuators were seated over the test section against the o-rings. Injection holes were located at the back of the platform and penetrate into the test channel An injection socket, connected to a syringe pump, was seated over the injection holes against on an o-ring. Fluids were injected through the holes using the syringe pump.

The oscillating flow experimental setup was also capable of performing steady flow experiments. By leaving one end of the test section open, steady flow and heat transfer experiments were conducted with the same test section configurations and sensors. Results were used as the benchmarks for the heat transfer of the oscillating flows. A valve and regulator were installed to adjust the flow velocity through the test section. A similar system was used to measure the Nusselt number and local pressure for steady gas flow through micro channels.

Experiments were conducted in both single channels and channel networks. The focus of single channel experiments is the measurement of local temperature and Nusselt number, while for experiments with networks, the focus was the practical applications. FIG. 6 shows a schematic drawing of a single test channel for heat transfer measurement. The determination of the Nusselt number required the measurement of heat flux, the wall temperature and the liquid temperature. Nusselt number were calculated by using Nuₓ=hₓD/k and hₓ=q/(T_{w}−Tᵢ), where hₓ is the local heat transfer coefficient, D is the hydraulic diameter of the flow channel, k is the conductivity of the liquid, T_{w} and T were local surface temperature and inlet bulk temperature, respectively. It is noted that the liquid mean (bulk) temperature at the inlet was used to replace the conventional local liquid temperature in above equation, since the temperature inside the micro channel is very difficult to measure without disturbing the flow. The use of the inlet bulk temperature to calculate the local Nusselt number also took into consideration the thermal potential for heat transfer surface to the cold liquid. A film heater was firmly mounted on the outer surface of the micro channel test section to supply a constant heat flux. By adjusting the supply voltage to the heater, the power input could be adjusted. The heat will be transferred to liquid by convection in the heated section and carried to cooling units as shown in FIG. 6. Ice-water at a constant temperature of 0° C. temperature will be forced to the cooling unit to remove the heat generated by the film heater.

Temperature measurement in microchannels presented a challenge in that commercially available temperature sensors were too large to fit inside the micro-channels without changing the flow characteristics. Therefore, thin film technology was used to fabricate thermocouples on the surface of the micro-channel Thin metal lines (1500 angstrom) and 200 μm wide was sputtered onto the micro-channel surfaces. The thermocouple junction spanned the width of the micro-channel to measure the mean wall temperature at a given location in the channel A standard thermocouple calibration was performed on several of the sensors to determine the consistency and reliability of the calibration from sensor to sensor. If required, a calibration was performed for each thin film thermocouple. This technique was successfully used in measuring wall temperatures in steady microchannel gas flows. In the same manner, temperature sensors were placed on the pyrex cap. Two temperature sensors were placed on both sides of the pyrex cap away from the micro-channel for the purpose of measuring the liquid inlet bulk temperature.

The average convection heat transfer coefficient was calculated by integrating Newtons Law of cooling with respect to the channel length. The heat flux into the micro-channel was measured from the power input to the heater. The Nusselt number was determined for a range of Reynolds numbers in a given micro channel By imposing a uniform heat flux into the micro-channel, one could measure a monotonic wall temperature profile with maximum value appearing at the exit for steady unidirectional flows and a parabolic wall temperature profile with maximum value appearing at the middle section of channel for oscillatory flows. Pressure measurement was carried out using highly accurate commercially available sensors. Specifically, omega px811 and px212 series pressure transducers will be coupled to omega om5 signal conditioning equipment. The hot-film anemometer was used to measure the velocities at the inlet and exit. The anemometer was calibrated in the steady flow conditions and was also compared with the mean velocity values based on the piezoelectric diaphragms deformations. The rate of pump power consumption was measured directly from the electrical input to the piezoelectric diaphragm. For steady flows, this value could be calculated from the measurement of pressure drop and flow rate.

Flow visualization experiments including measurements of flow streaming and displacement, was conducted in identical microchannel geometries without the structures of cooling unit, temperature sensors and pressure tabs. The procedures were similar to the ones used in preliminary work.

A computer model would selectively simulate streaming velocity and Nusselt number in steady oscillating flow using a number of predetermined flow geometry including single channel and channel networks. Typical geometries included rectangular cross-sectional tapered geometry and bifurcating angle for pipe network. The rectangular cross-sectional geometries were favorable because it was cost effective to fabricate and as well as to construct numerical grid. Flow geometries and operating parameters with the ‘good’ computational results were selected for further experimental verifications. The ‘good’ geometries are defined relative to their respective targeted functions. For example, at a given experimental conditions, the greater streaming displacement indicate a better performance in fluid transport and overall heat transfer rate while the maximum local heat transfer rate was judged by the maximum stream velocity. The major performance parameters to be measured and reported include: maximum temperature lift, Nusselt number and the rate of heat transfer as functions of Reynolds number and power consumption.

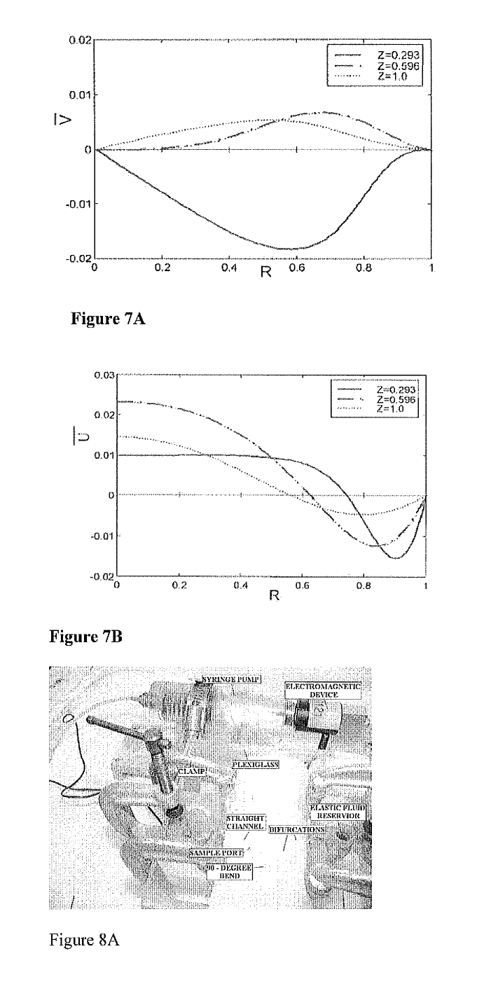

The N-S equations for axisymmetrical oscillating flow of an incompressible, Newtonian fluid contained in a semi-infinite, straight rigid tube. For the problem considered, the flow was driven by sinusoidal oscillations of a piston at the end of the tube were solved. The detailed method was described in the paper by Goldberg, Zhang and Tran, (1999). FIG. 7 displays the distribution pattern of streaming velocity U and V as a function of radius position R and axial position Z in the entrance region of a circular tube. The Reynolds number and the Womersley number used in calculation equal to 1 and 5, respectively. FIG. 7 demonstrated the phenomenon of bi-directional streaming flows as indicated by positive and negative U values along the tube radial coordinates. Fluid mixing also occurred as indicated by non-zero

V velocity values. The magnitude of streaming velocity and mixing decreased as the axial distance from the entrance increase.

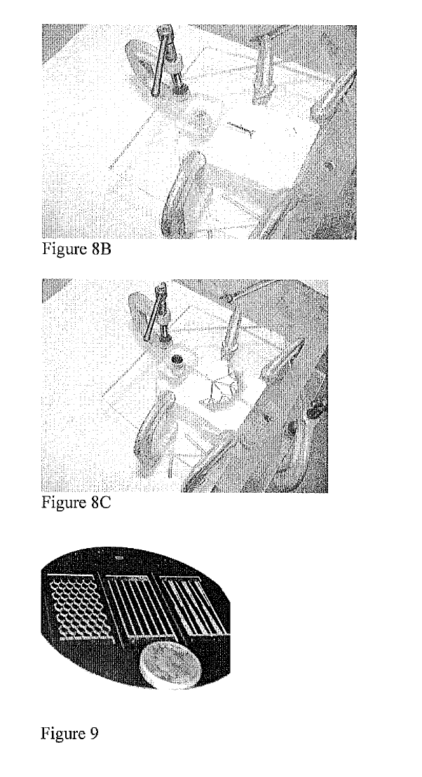

FIG. 8A shows a photo of the experimental setup. Flow was generated by an oscillating syringe, which was in turn driven by an electromagnetic device. An electrical signal generator with variable voltage and frequency output controlled the electromagnetic device.

Open mini channel networks, with square cross-sectional channel geometries of 0.8×0.8 mm ( 1/32 inch× 1/32 inch) were milled into a palm-size transparent Plexiglas panel. Tube fittings were glued to another Plexiglas panel forming a channel inlet and an outlet. Two panels were then clamped together to form the closed fluid channels. A small water balloon was connected to the outlet and served as an elastic water reservoir. Sample ports of diameter 0.4 mm were drilled into the panel and were sealed by Scotch tape during the experiments. To facilitate the viewing of flow patterns, a mixture of four-parts food coloring (McCormick & Co. Inc., relative density=1) and one-part liquid soap (Softsoap, Inc, relative density=1.25 by volume) was used. The purpose of using liquid soap was to reduce the diffusivity of mixture in water.

The experiment started by filling with water, once air bubbles trapped in the channels were removed. One drop of red dye and one drop of green dye were injected through the sample port using a PS-26 (Pepper & Sons) needle. Each injection process took about 3 seconds. FIGS. 8B and 8C are the photos of the fluid mixing and propulsion experiments in a branching channel network. Each mother tube was branched into four daughter tubes. At branch generation III, the number of channels reaches 16. FIG. 8B was photographed at the time interval of T=6 s. Although oscillating amplitude was only 4 times of the diameter, fluid coloring was propelled quickly into branching networks. FIG. 8C showed the pattern of color distribution at T=16 s. The red and green dyes initially located near the sample port are mixed and distributed almost uniformly in entire generation III channels as well as in fluid reservoirs, demonstrating the highly efficient bi-directional fluid propulsion and mixing.

The calculated the Reynolds number and the Womerserly number for the experiment is 20 and 35, respectively. These numbers were reduced for micro channels flows (d is in the order of 0.2 mm and smaller). As discussed before, the typical entrance length for a low Reynolds number flow was about a few tube diameters. The relative ‘long’ straight channel section used in preliminary experiment by far wasn't an optimum geometry for creating streaming Conical channels and short-connected bifurcation networks were the better geometries. On the other hand, effects of flow streaming are accumulative. Flow streaming can persist much longer than the flow entrance length as demonstrated in the experiment.

There is a feasibility of fluid propulsion and mixing and indicated the great potentials of micro/mini channel heat transfer enhancement using flow streaming

A challenging and time-consuming part is the fabrication of the micro-channels. To verify the feasibility a wafer with multiple shape channel networks for the project was successfully constructed. FIG. 9 shows a picture of wafer consisting of three preliminary micro channel networks. The diameter of the wafer is 4 inches and the depth of the channels is 800 μm. The geometries of channel networks include: 1) a bifurcation network, the geometry crucial to HFV techniques, 2) a network of parallel straight tubes, to be used for benchmark test, and 3) a network of tapered channels. The single tapered channel has been studied extensively but neither tested in micro-scale or in network formats. Other geometries may be designed as desired. For experiments using channel networks, micro film heater and two ice-water cooler were placed over the top surface of the network.

The concept of mini/micro channel heat exchanger using oscillating streaming flow has many potential advantages in practical applications including the micro/mini heat transfer device which is compact and reliable. This is because: a) most micro-fluidic systems require close-looped (or a two-way) piping system, e.g., pipes connected to the inlet and outlet of a pump, while the steady bi-directional streaming can be achieved in a one-way channel; b) no micro-valves are needed for streaming fluid propulsion. Various valves are needed in a typical micro pump system, such as check valves or pairs of diffusers/nozzles and micro-pump losses are dominated by the head losses in micro-valves; and c) this micro-fluidic system could offer improved reliability because of its simple structure. There are no moving parts, other than the piezoelectric diaphragm action itself.

The application of streaming flow heat transfer is particularly attractive in micro systems. This is because: a) the volume of a micro system is so small that a large oscillation volume is easier to generate, b) the conventional forced convection heat transfer is difficult to accomplish commercially in micro/mini channels since the design and manufacture of a micro pump is a great challenge, and c) the research and development on other micro heat transfer device is still at its infant stage.

The distance a fluid can travel is limited by its oscillating volume for conventional oscillation flow heat transfer while there is no such problem for oscillation streaming flow heat transfer devices as discussed before.

The proposed device can be easily manufactured using the current thin film deposition techniques. Piezoelectric diaphragms can be fabricated by simply depositing piezoceramic material to one or more diaphragms. Piezoelectric diaphragms have the inherent advantage of low voltage and high pump-head; it can also be designed to assemble multi-diaphragms in series to increase the total displacement. The advantages of compactness and the manufacture method described above would enable the device at a much smaller scale. It can be integrated into the microchip components at the design and fabrication stage, enabling a compact chip with an onboard cooling system to be employed, where conventional cooling strategies cannot be employed.

The use of the piezoceramic material microfluidic system is more scalable in device design and easy to control electronically. The surface temperature can be controlled with closed loop control strategies. For example, a thermocouple surface temperature measurement can provide the feedback signal. The rates of heat transfer are then controlled operating voltage and frequency. The power supply is one of the challenging problems for electro-kinetic fluid propulsion device while the piezoelectric diaphragm can be designed to operate on regular powers supplies or even battery power, which provide engineers with greater design flexibility and make the micro system feasible.

However, the proposed device also has many disadvantages. The major disadvantage of using this micro heat transfer device is the requirement of two cooling units (although the total cooling surface is same) for its heat transfer to be better than that of steady flow. The other disadvantage is the increased friction losses during the flow oscillation, particularly at a high frequency.

The technology can be used to manufacture a system-on-a-chip where device chip, cooling system will be integrated into one package. Regular battery power will be used to operate the device. The interface materials effect is greatly reduced by a direct contact of cooling fluid with the device chip surface.

In addition to this mini/micro heat transfer enhancement technology, there is a wide range of potential new applications including Lab-on-chip (LOC) technology, micro drug delivery and control, micro mass transfer enhancement, micro reactor, micro filter and micro fuel cell.

In light of the foregoing, it will now be appreciated by those skilled in the art that various changes may be made to the embodiment herein chosen for purposes of disclosure without departing from the inventive concept defined by the appended claims. Non limiting examples of such changes including using

What I now claim is:

1. A micro/mini heat exchanger and heat pipe, said micro/mini heat exchanger and heat pipe including at least one channel wherein, oscillating generated streaming flow is passed therethrough.

2. The micro/mini heat exchanger and heat pipe of claim 1, wherein the oscillating flow can be generated by diaphragm pump, vibrator, electrokinenatic force, and thermal acoustic force.

3. The micro/mini heat exchanger and heat pipe of claim 1, wherein the oscillating flow has an unsymmetrical crosssectional flow geometry

4. The micro/mini heat exchanger and heat pipe of claim 3, wherein the unsymmetrical crosssectional flow geometry includes a tapered channel such that one end has a smaller crosssectional geometry and the other end has a larger cross-sectional geometry.

5. The micro/mini heat exchanger and heat pipe of claim 4, wherein the unsymmetrical crosssectional flow geometry has an area such that the area smoothly increases from one end to the other end.

6. The micro/mini heat exchanger and heat pipe of claim 4, wherein the geometry of the channel may include any shape including circular, rectangular, triangle and any polygonal shape.

7. The micro/mini heat exchanger and heat pipe of claim 4, wherein the tapered channel is connected in a series including bi- or three-dimensional multi-bifurcation structures, tube-in-tube structures, one or multiple partitions in conduit; and bending pipes.

8. The micro/mini heat exchanger and heat pipe of claim 1, wherein a heat pipe temperature control includes the use of the oscillating amplitude and frequency.

9. The micro/mini heat exchanger and heat pipe of claim 8 wherein the streaming velocity is the function of oscillating frequency and amplitude.

10. A microchip including a micro/mini heat exchanger to cool said microchip.

11. The microchip of claim 10 wherein, the microchip includes micro-channels formed by photolithography.

12. A process of forming high speed, high density micro scale devices, micro sensors and micro machines wherein, said process includes providing micro channels to pass oscillating streaming flow therethrough.
